(19) United States
(12) Patent Application Publication
(10) Pub. No.: US 2012/0069509 A1
(43) Pub. Date: Mar. 22, 2012

(54) METHOD FOR FABRICATING DISPLAY PANEL

(75) Inventor: Tazoh Ikeguchi, Osaka (JP)

(73) Assignee: SHARP KABUSHIKI KAISHA, Osaka (JP)

(21) Appl. No.: 13/375,710

(22) PCT Filed: May 28, 2010
(86) PCT No.: PCT/JP2010/059099

§ 371 Date: Dec. 1, 2011

(30) Foreign Application Priority Data
Jun. 12, 2009 (JP) 2009-141473

(51) Int. Cl. H05K 7/00; H01J 9/00

(52) U.S. Cl. 361/679.01; 445/24

(57) ABSTRACT

With this method, it is possible to etch a desired surface of a display panel substrate without excesses or deficiencies. A method for fabricating a display panel includes the steps of forming circuit wiring in each of a plurality of areas that are to become display panels on a substrate member, forming protective films (9a, 9b) for covering at least part of the substrate member and the circuit wiring so as to cross a cutting line (c) of the substrate member for separating each of the display panels, separating each display panel by cutting the substrate member along the cutting line (c) after the protective films (9a, 9b) are formed, and etching a cut face of the separated display panel.

### TECHNICAL FIELD

The disclosure of the present invention relates to a display panel having a substrate such as, for example, a liquid crystal display panel and to a method of fabricating same.

### BACKGROUND ART

In order to make a display panel having a substrate thin, the substrate may be etched. During this etching, applying a resin as a resist film in order to prevent etching of the areas not desired to be etched (for example, TFT terminal surfaces and the like) is being proposed (for example, see Patent Document 1).

### RELATED ART DOCUMENTS

### Patent Documents

Patent Document 1: Japanese Patent Application Laid-Open Publication No. 2007-81870

### SUMMARY OF THE INVENTION

### Problems to be Solved by the Invention

Etching of a substrate can be performed to insure the strength of the substrate. For example, in the case of a liquid crystal display panel, by etching all surfaces except for film surfaces (surfaces where TFT or CF is formed) of a TFT substrate and a CF substrate, micro cracks of the substrates can be removed and the strength can be insured. During this etching, for example, in order to perform selective etching of a side edge face without etching the film surface of the substrate, a protective resin (etching prevention resin) needs to be applied to parts of the film surface that are not to be etched.

However, it is difficult to let this protective resin reach without excesses or deficiencies to edges and protective parts (parts bordering with the side edge faces) of the film surface of the substrate. It is not rare that the protective resin sticks out beyond the film surface and to the side edge face (causing drooping) or that the protective resin does not reach the bordering parts and thus parts near the edges of the film surface are exposed. In other cases, when a jig for etching is fixed to the protective resin, sticking out (drooping) of the protective resin to the substrate side edge face happens often.

As described above, if the protective resin sticks out to an etching surface of the substrate, then when etching of the substrate is performed, the parts where the resin sticks out (drooping parts) are not etched. Therefore, small cracks of the substrate remain and the substrate becomes weak against bending stresses. On the other hand, on non-etching surfaces of the substrate, if there are parts where the protective resin has not reached (non-covered parts), etching continues from the etching surfaces to the non-covered parts, thereby making front edges of the substrate thin and easy to break.

Accordingly, an object of the present invention is to provide a display panel in which etching of desired surfaces of a display panel substrate without excesses or deficiencies becomes possible or to provide a method of fabricating the same.

### Means for Solving the Problems

In order to achieve the above objective, a fabrication method disclosed in the present application includes forming circuit wiring in each of a plurality of areas that are to become display panels on a substrate member, forming a protective film for covering at least a part of the substrate member and the circuit wiring so as to cross a cutting line of the substrate member for separating each display panel, separating respective display panels by cutting the substrate member along the cutting line after the protective film is formed, and etching the cut face of the separated display panel.

According to the above fabrication method, the display panel is separated in a state in which the protective film is formed on at least one side of a rectangular area that the display panel occupies on the substrate member. This way, the protective film reaches out to edges of the substrate (that is, cut face) in the separated display panel. That is, a side edge face of the protective film and a side edge face of the substrate are formed in the same plane in the cut face. Thus, missing of the protective film on a non-etching surface or sticking out the protective film to an etching surface can be prevented. As a result, desired surfaces can be etched without excesses or deficiencies and, further, the strength of the substrate can be secured.

In the above fabrication method, the circuit wiring formed in each of the plurality of areas that are to become display panels may include external connection wiring that connects to a part external to the display panel, the protective film may be formed so as to cover an area where the external connection wiring is formed and to expose a terminal portion of the external connection wiring that is to be connected to external wiring, and during the etching, the cut face of the display panel may be etched in a state in which an additional film is further provided on the exposed terminal portion and the additional film is removed after the etching.

This way, the cut face can be etched without excesses or deficiencies when the cut face is etched. Also, by removing the additional film after the etching to expose the terminal portion, a configuration in which the external wiring can be connected becomes possible.

In the above described fabrication method, the circuit wiring formed in each of the plurality of areas that are to become display panels may include external connection wiring that connects to a part external to the display panel, the protective film may be formed so as to cover an area where the external connection wiring is formed and to expose a terminal portion of the external connection wiring that is to be connected to external wiring, and during the etching, the cut face of the display panel may be etched in a state in which wiring that is covered with resin is connected to the exposed terminal portion.

This way, since the wiring covered with resin is connected to the terminal portion of the external connection wiring that is not covered with the protective film, the non-etching portion can be covered. Therefore, protective film formation and etching step can be performed efficiently.

In the above described fabrication method, the protective film may be formed by forming an alignment film covering a display area of the display panel so as to cross at least one side of the periphery of a rectangular area that each display panel occupies on the substrate member.

This way, since the protective film is formed during the process of forming an alignment film, the protective film can be formed even more efficiently.

The display panel disclosed in the present application has a substrate, circuit wiring for displaying an image formed on a display area of the substrate, and a protective film that covers at least a part of the substrate and the circuit wiring, wherein a side edge face of the protective film and a side edge face of the substrate are formed in a same plane.

Because of the above configuration, in at least one side edge face of the display panel, the side edge face of the substrate can be etched without excesses or deficiencies.

In the above described display panel, the circuit wiring may include external connection wiring that connects to a part external to the display panel, the protective film may be formed so as to cover an area where the external connection wiring is formed and to expose a terminal portion of the external connection wiring that is to be connected to external wiring, and wiring covered with resin may be connected to the exposed terminal portion.

The protective film covers an area where the external connection wiring is formed, and can be an alignment film including a side edge face on a same surface as at least one side edge face of the side edge faces of the substrate.

### Effects of the Invention

According to the present invention, it becomes possible to etch desired surfaces of a display panel substrate without excesses or deficiencies.

### BRIEF DESCRIPTION OF THE DRAWINGS

FIG. 1 is a plan view showing a liquid crystal display panel according to Embodiment 1.

FIG. 2 is a cross sectional view along the line A-A in FIG. 1 of the liquid crystal display panel.

FIG. 3 is a flow diagram showing an example of a processing flow in fabrication steps of a liquid crystal display panel.

FIG. 4 is a flow diagram showing an example of fabrication steps of an array substrate.

FIG. 5 is a top perspective view of an intermediate product in a state in which a large sized array substrate and opposite substrates are attached together.

FIG. 6 is a cross sectional view along the line A-A in FIG. 5.

FIG. 7 is a cross sectional view of a single cell, that is, a liquid crystal display panel provided with a protective resin.

FIG. 8A is a view showing a liquid crystal display panel being etched as viewed from a panel surface side.

FIG. 8B is a cross sectional view along the line A-A in FIG. 8A.

FIG. 9 is a cross sectional view of a liquid crystal display panel according to Embodiment 2.

FIG. 10 is a flow diagram showing an example of a processing flow in fabrication steps of the liquid crystal display panel according to Embodiment 2.

FIG. 11 is a top perspective view of an intermediate product in a state in which a large sized array substrate and an opposite substrate are attached together.

FIG. 12 is a cross sectional view along the line A-A in FIG. 11.

FIG. 13A is a view of a liquid crystal display panel being etched as viewed from a panel surface side.

FIG. 13B is a cross sectional view along the line A-A in FIG. 13A.

### DETAILED DESCRIPTION OF EMBODIMENTS

Specific embodiments of the present invention are described below by referring to the drawings. Here, embodiments described below show configuration examples in which a display panel of the present invention is embodied as a liquid crystal display panel. However, the display panel of the present invention is not limited to the liquid crystal display panel. The display panel of the present invention is applicable to any appropriate display panels using a substrate having pixels disposed in a matrix manner thereon (for example, EL display device, plasma display and the like). Also, the display panel of the present invention can be applied to a curved surface display.

Also, for the sake of description convenience, each of the drawings referred to below shows only simplified main members necessary for describing the present invention among constituent members of the embodiments of the present invention. Accordingly, the display device of the present invention may include any appropriate constituent members that are not shown in each of the drawings referred to in the present specification. Also, dimensions of the members in each of the drawings are not accurate reflections of actual dimensions of the constituent members and dimensional ratio and the like of each member.

### Embodiment 1

### Configuration of a Display Panel

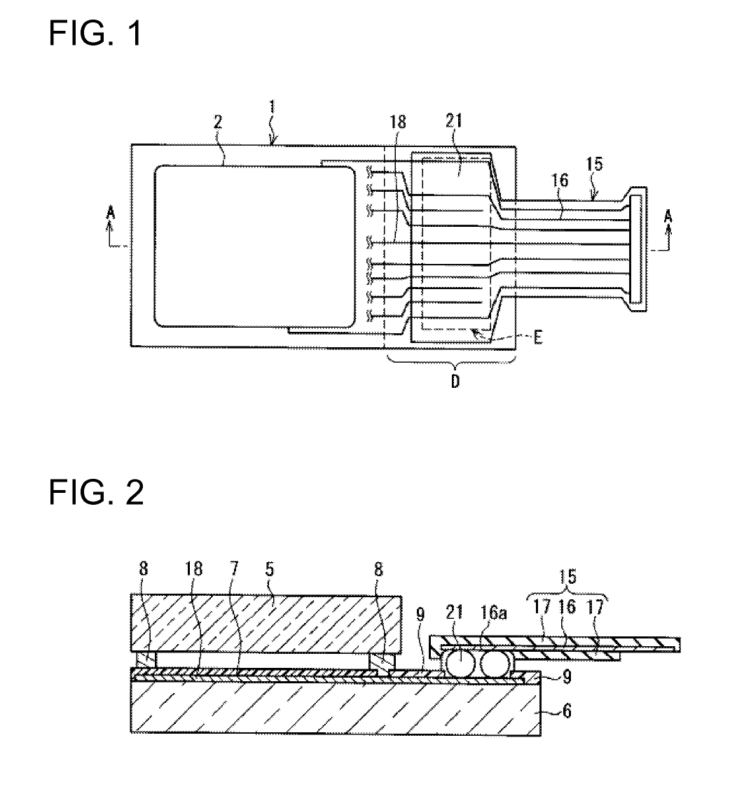

FIG. 1 is a plan view of a liquid crystal display panel according to the present embodiment. FIG. 2 is a cross sectional view of the liquid crystal display panel along the line A-A in FIG. 1. In the example shown in FIG. 1 and FIG. 2, a liquid crystal display panel 1 has an array substrate 6 having a plurality of active elements formed thereon (not shown), an opposite substrate 5 and a liquid crystal layer sandwiched between these substrates.

The array substrate 6 is a substrate having TFTs (Thin Film Transistors) (not shown), which are source switching elements, pixel electrodes and the like formed in a matrix manner on a transparent glass substrate. Also, the array substrate 6 has source electrodes and gate electrodes that are connected to the switching elements and also external connection wiring 18 for extracting the electrodes outside. In FIG. 1, a part of the external connection wiring 18 is omitted. Alignment films 7 are formed on surfaces of the liquid crystal layer side of the array substrate 6 and the opposite substrate 5. For the alignment film 7, rubbing processing is performed in a predetermined rubbing direction and liquid crystal molecules (not shown) in the liquid crystal layer are aligned in the predetermined direction.

The opposite substrate 5 is a substrate having, for example, three color filter layers of red, green and blue formed on a transparent glass substrate. Although they are not shown, the opposite substrate 5 has an opposite electrode and the alignment film formed thereon.

The array substrate 6 is connected to the opposite substrate 5 by a seal 8. The liquid crystal layer is encapsulated by the array substrate 6, the opposite substrate 5 and the seal 8.

In the array substrate 6, the area not overlapping with the opposite substrate 5 is provided with terminals for connecting the external connection wiring 18 to an external part. Hereinafter, this area is referred to as a terminal part D. The terminal part D is provided with the external connection wiring 18 formed on the array substrate 6 and a protective film 9 covering the external connection wiring 18. As shown in FIG. 2, a side edge face of the protective film 9 and a side edge face of the substrate 6 are formed in the same plane. That is, the side where the terminal part D is disposed on the array substrate 6 is covered by the protective film 9 up to an edge. Here, for the sides not covered by the protective film 9, the alignment film covers the array substrate 6 up to edges.

A part of the terminal part D has an area E that is not covered by the protective film 9. That is, a part of the protective film 9 is carved out. A flexible printed circuit (FPC) 15 is connected to this area E through an anisotropic conductive film (ACF) 21. The FPC 15 has conductive wiring 16 such as copper wires and the like, and an insulating body layer 17 covering the conductive wiring 16. Specifically, a base film that includes a polyimide film or the like and that has flexibility is used as the insulating body layer 17. The conductive wiring 16 is formed using copper foils or the like on both surfaces of the base film. An insulating film that protects the conductive wiring 16 is further provided. Also, a terminal part 16a where the conductive wiring 16 is exposed by removing a part of the insulating film is formed in the FPC 15. In addition, the terminal part 16a of the FPC 15 is connected electrically to the area E formed in the terminal part D of the array substrate 6 by a connecting member such as the ACF 21, for example. This way, the FPC 15 is connected to the external connection wiring 18 that is extracted to the terminal part D of the array substrate 6.

Electronic components (not shown) such as a power supply circuit and a control circuit, for example, may be mounted on the FPC 15. Since the FPC 15 is connected to the external connection wiring 18, control signals, power supply voltages, and the like can be supplied to pixel circuits on the array substrate 6 through the external connection wiring 18 from the electronic components mounted on the FPC 15. Here, a driver circuit for driving switching elements may be formed also on the array substrate 6 by the COG (Chip on Glass) method.

Fabrication Method

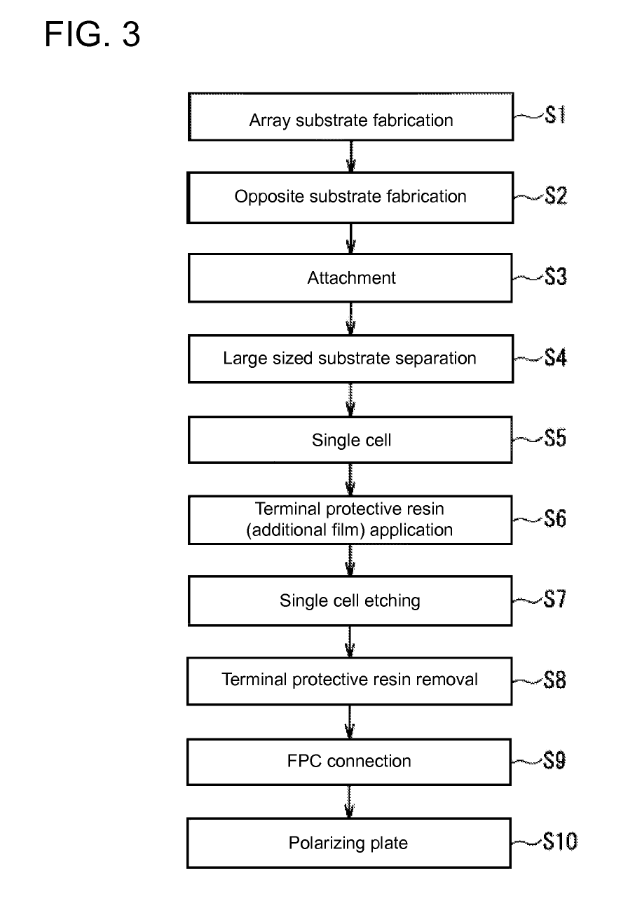

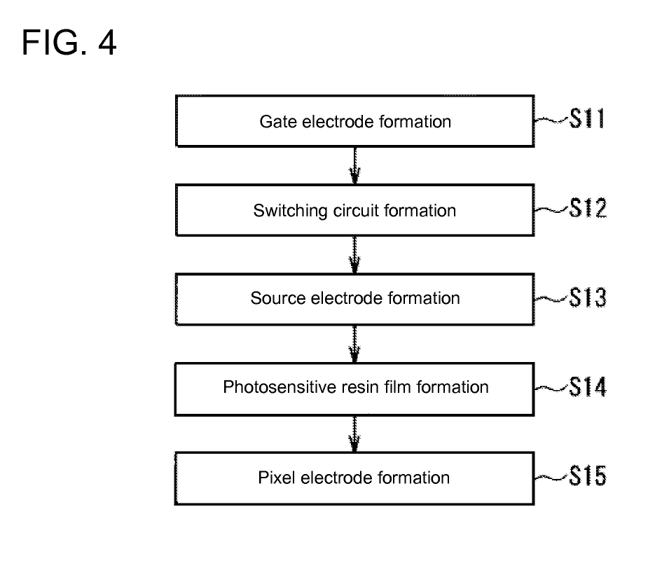

Next, a fabrication method of a liquid crystal display panel according to the present embodiment is described. FIG. 3 is a flow diagram showing an example of a processing flow in fabrication steps of a liquid crystal display panel. In the example shown in FIG. 3, initially, an array substrate is fabricated (S1). FIG. 4 is a flow diagram showing an example of fabrication steps of the array substrate. In the example shown in FIG. 4, gate electrodes, switching circuit, and source electrodes are formed in each of a plurality of areas that are to become the liquid crystal display panels on a mother glass that is an example of a substrate member (S11-S13). For example, the gate electrodes include a plurality of gate wires disposed in the row direction of pixels, and the source electrodes include a plurality of source wires disposed in the column direction. Near intersections of the gate wire and the source wire, switching elements (for example, TFTs (Thin Film Transistors)) are provided. That is, switching elements are formed in a matrix manner. Also, the external connection wiring for extracting the gate electrodes and the source electrodes together outside is formed. For example, the gate electrodes and the source electrodes are extracted to an area adjacent to the display area (the area D shown in FIG. 1) by the external connection wiring and the terminal part for connecting to an external part is formed in the area.

Next, a resin film covering the mother glass surface is formed (S14). This resin film becomes the protective film 9 shown in FIG. 2. This way, the resin film is configured so as to cross a separation boundary (cutting line) of cells (individual liquid crystal display panels). As described, the resin film is formed so as to cross the separation boundary of cells before separating the cells, each of which are to become the liquid crystal display panel. Thus, the resin film can cover up to the separation edges of the cells after separation. This way, the protective film (resin film) for protecting terminals can be formed accurately and without excesses or deficiencies on the terminal part D. As a result, as described below, accurate etching of the cut face becomes possible. Also, the resin film is formed so as to cover the terminal part of the extracted external connection wiring, and is patterned so that the external connection wiring is exposed in a part of the terminal part. For the resin film, a photosensitive resin material such as a photosensitive acrylic resin or the like can be used, for example. In the resin film formation steps, a photosensitive acrylic resin pattern can be formed by photolithography. After the formation of the resin film, patterning is performed for pixel electrodes by sputtering ITO, for example (S15). After this, the alignment film is formed in the area including the display area.

Specifically, this resin film can be made into an overcoat film by the photosensitive acrylic resin for easing the unevenness of the surfaces of the array substrate and the opposite substrate. Forming the overcoat film pattern can be realized by performing a slot or spin application of the resin on both of the substrates that are completed in a substrate state, and by removing only the pattern for the part of the terminal in a similar manner as described above by the exposure.

Referring to FIG. 3 again, the opposite substrate is fabricated after the array substrate fabrication. Color filters, black matrices, opposite electrodes and the like, and an alignment film and the like are formed on a transparent mother glass. For the color filters, a filter layer of three colors of red, green, and blue is formed in each display area of the plurality of liquid crystal display panels, for example.

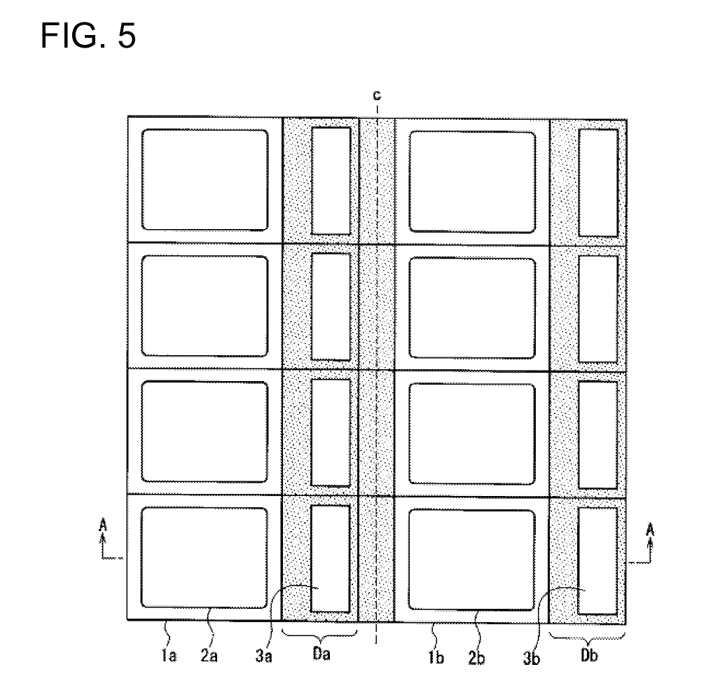

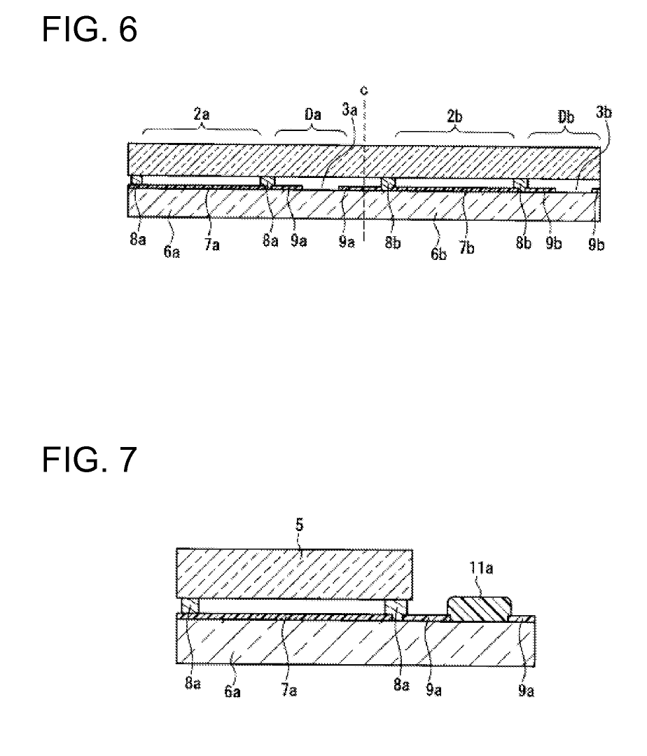

The large sized array substrate including the mother glass is attached to the large sized opposite substrate by the seal (S3). FIG. 5 is a top perspective view of an intermediate product in a state in which the large sized array substrate and the opposite substrates are attached together. FIG. 6 is a cross sectional view along the line A-A in FIG. 5. A configuration when viewed from top of a flat surface of the array substrate through the opposite substrate is shown in FIG. 5. Also, the dotted line c indicates the cutting line (separation line). The resin films (protective films 9a, 9b) are formed in the areas hatched with dots in FIG. 5.

In FIG. 5 and FIG. 6, respective cells include the display areas 1a, 1b and terminal areas Da, Db. The protective films 9a, 9b are formed to cover the terminal parts Da, Db, and are extended and formed to the position crossing the separation line c. Also, the protective films 9a, 9b are patterned so that the external connection wiring (not shown) is exposed in parts of the terminal parts Da, Db. That is, parts 3a, 3b are located in the terminal parts Da, Db so that they are not covered by the protective films 9a, 9b in the areas not in contact with the periphery of the cell.

After the array substrate 6a, 6b and the opposite substrate 5a, 5b are attached together as described, each cell is separated (S4, S5). For the separation, the scribe and break method can be used, for example.

A protective resin (an example of additional film) covering the parts 3a, 3b that are not covered by the protective films 9a, 9b (that is, the parts where the external connection terminal is exposed) is formed in each cell (S6). This protective resin is provided to protect the array substrate 6a, 6b and the external connection wiring from an etching liquid in a later etching step. FIG. 7 is a cross sectional view showing a single cell, that is, the liquid crystal display panel provided with the protective resin. In the example shown in FIG. 7, a protective resin 11a is provided in the part not covered by the protective film 9a. Further, a jig for etching is attached to the protective resin 11a.

Here, as shown in FIG. 7, the protective film 9a and the array substrate 6a are formed in the same plane in the side edge face at the separation line c side after the separation of the cells. That is, the protective film 9a is formed up to the separation edge on the surface of the array substrate 6a.

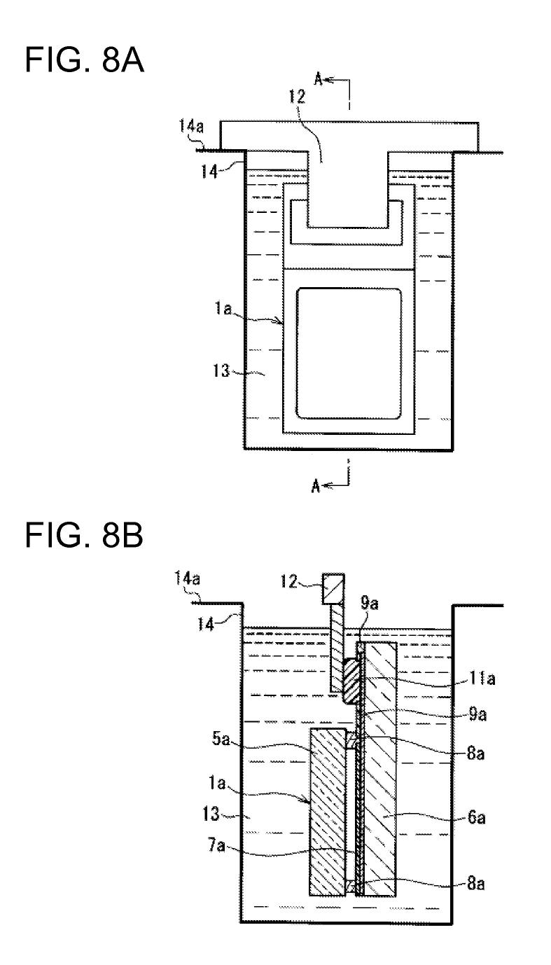

The cell (liquid crystal display panel), as fabricated above, is submerged in a glass etching liquid (for example, 3 to 5% hydrofluoric acid liquid) for 1 to 10 minutes to etch the side edge faces of the glass (S7). FIG. 8A is a view from a panel surface side during etching of the liquid crystal display panel. FIG. 8B is a cross sectional view along the line A-A in FIG. 8A. In the example shown in FIG. 8A and FIG. 8B, the liquid crystal display panel is stabilized in the etching liquid 13 by hanging the jig connected to the protective resin 11a on a frame 14a of a container containing the etching liquid 13. This way, the surface of the opposite substrate 5a that is opposite of the surface facing the array substrate 6a and its side edge face, and the surface of the array substrate 6a that is opposite of the surface facing the opposite substrate 5a and its side edge face are exposed to the etching liquid. Therefore, the surfaces from which the glass is exposed in the opposite substrate 5a and the array substrate 6a can all be etched.

The liquid crystal display panel is taken out with the jig after etching for a certain amount of time, and the etching is completed by rinsing with pure water and drying by warm air. Following this, a polarizing plate is attached, and then the protective resin 11a is removed (S8), and the FPC is connected to the part where the external connection wiring of the terminal part D is exposed (S9). For example, a resin ACF bonder which is a conductive material and has a tape like shape is attached to the FPC and is pressure-bonded provisionally to the FPC at 80° C. This FPC is pressured to the part of the liquid crystal display panel in which the external connection wire is exposed by a head heated at 200° C., and the FPC is pressure-bonded permanently. Following the pressure bonding of the FPC, a module is completed by processes such as mounting ICs and the like. Here, a backlight device may be provided on the backside of the liquid crystal panel. This way, the liquid crystal display device provided with the liquid crystal panel and the backlight device is fabricated.

Effects and Others

According to the present embodiment, the array substrate 6 after the cell separation can be covered by the protective film 9 up to the separation edges of the cell because the protective film 9 is provided on the separation line before the cell separation. Therefore, the protective film 9 for protecting the terminal can be formed on the array substrate 6 without excesses or deficiencies, and accurate etching of the cut face becomes possible. For example, in order to selectively etch side edge faces of a glass, it would be necessary to apply the protective resin on parts that are not to be etched, but, it is not easy to apply thoroughly the protective resin up to edges and protective parts of the substrate. The protective resin may also droop over an etching surface (substrate cut surfaces of the substrate). In other situations, when the protective resin and the etching jig are fixed, the protective resin may also droop over an etching surface. In such a situation, etching of the part where the protective resin is drooping is prevented when etching the glass substrate. Thus, micro cracks remain and the substrate becomes weak against bending stress. On the other hand, the part where the protective resin application is lacking, etching continues. Thus, front edges of the substrate become thin and easy to break. According to the present embodiments, as described above, the protective film can be formed without excesses or deficiencies. Thus, occurrences of these situations can be prevented without particularly making the fabrication steps complicated.

### Embodiment 2

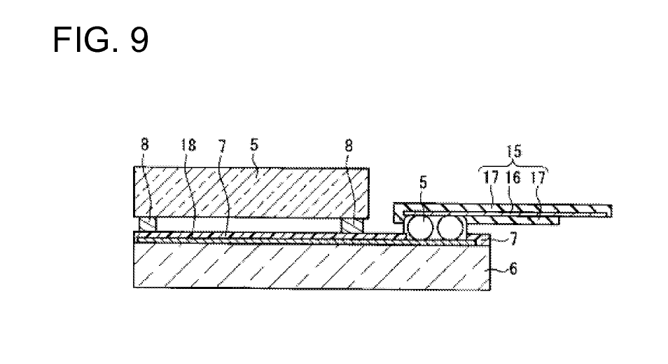

FIG. 9 is a cross sectional view of a liquid crystal display panel according to Embodiment 2. In FIG. 9, the same reference characters are assigned to the same members as in the liquid crystal display panel shown in FIG. 2. In the liquid crystal display panel shown in FIG. 9, an alignment film 7 is formed to extend to a terminal part D and further to edges of an array substrate 6. That is, the alignment film 7 is also performing the role of the protective film 9 of Embodiment 1.

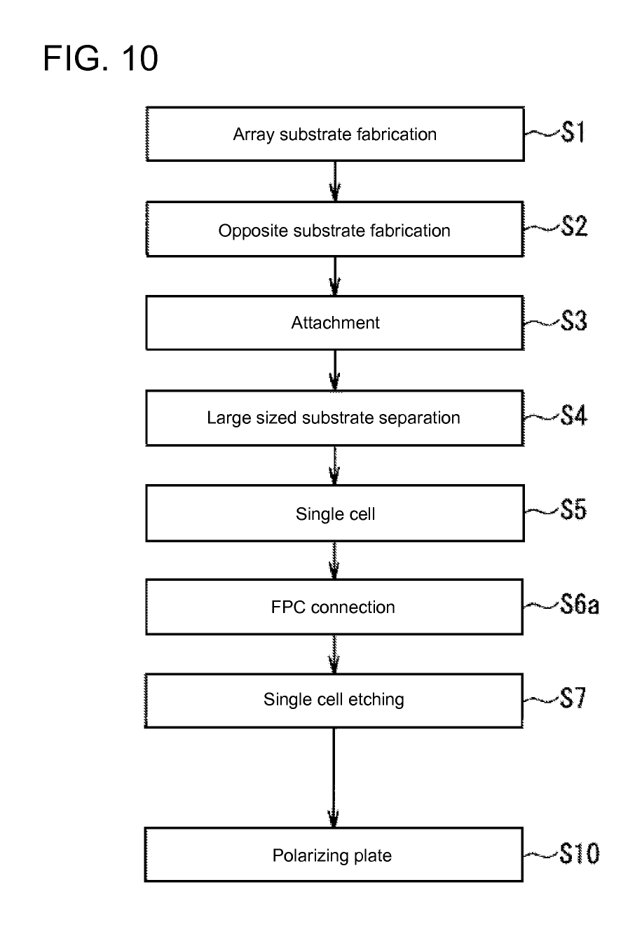

FIG. 10 is a flow diagram showing an example of a processing flow in fabrication steps of the liquid crystal display panel according to the present embodiment. In the example shown in FIG. 10, the liquid crystal display panel is fabricated as follows. An array substrate 6 having a plurality of patterns of the liquid crystal display panels formed thereon is attached to an opposite substrate 5 having a plurality of black matrices and color filters for the liquid crystal display panels formed thereon. Following this, the liquid crystal display panels are made by separating them. In these fabrication steps, an FPC is connected before etching.

An alignment films 7 of a polyimide resin is printed on each of the glass substrates in the array substrate fabrication (SS1) and the opposite substrate fabrication (S2). Conventionally, at this time, printing pattern of the alignment film 7 was usually printed only in the part corresponding to the display area and was not printed in non-display areas. Particularly, since alignment is not needed in the part where there are terminals for connecting circuit wiring to an external part, the alignment film was not usually provided in this part. In contrast, in the present embodiment, printing pattern of the alignment film 7 is formed so as to further extend from the display area and cross the separation line.

After the patterning of the alignment films 7a, 7b, rubbing is performed. The array substrate 6a, 6b and the opposite substrate 5a, 5b having been provided with the alignment films 7a, 7b as described above are attached together by a seal printing processing and a liquid crystal drip treatment (S3).

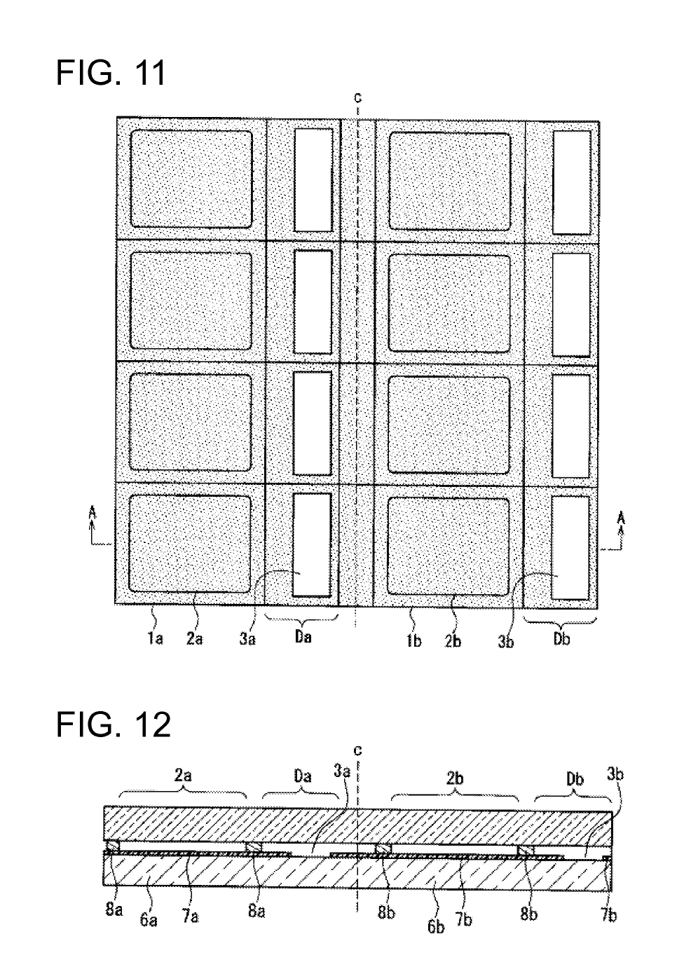

FIG. 11 is a top perspective view of an intermediate product in a state in which a large sized array substrate and an opposite substrate are attached together. FIG. 12 is a cross sectional view along the line A-A in FIG. 11. In the present embodiment, the alignment film 7 is provided in the area hatched by dots in FIG. 11. That is, the alignment films 7a, 7b are provided so as to cover not only display areas 1a, 1b, but also to cover terminal parts Da, Db adjacent to the display areas where external connection wiring is extracted and to be connected to an external part. The alignment films 7a, 7b are formed by further extending up to the position crossing the separation line c between the cells. Also, the alignment films 7a, 7b are patterned so that the part where the terminals are connected to the FPC is not printed by the alignment films 7a, 7b in the terminal parts Da, Db. This way, the external connection wiring (not shown) is exposed in parts 3a, 3b that are not covered by the alignment films 7a, 7b.

Next, the large sized substrate is separated in units of individual cells (S4, 5a). In the separation steps, initially, scribe lines are formed vertically and horizontally corresponding to the outline of the cell by a wheel on the opposite substrate. Next, scribe lines are formed corresponding to the cell outline on the array substrate side by the wheel. When scribe lines are formed, errors due to looseness in the wheel axis, scribe lines being formed in a slanted manner or the like may occur and deviation from the intended lines may happen. However, in the present embodiment, even if such errors occur, the part where polyimide is printed as the alignment film will be to be separated. Accordingly, the separation edges of each cell after the separation will be in a state in which polyimide resin is coated.

The FPC is electrically connected through the ACF tape to the part where the alignment film 7 is removed in the terminal part D after the separation of the cells (liquid crystal display panels). Also, the part where the alignment film 7 is removed, that is, the exposed surface of the array substrate, is covered by this FPC (S6a). As described above, by attaching the FPC to the terminal connection part of the cell (liquid crystal display panel) before etching, non-etching part can be covered. Thus, separate protective resin or the like is unnecessary. Also, even if the ACF bonder resin exudes during connection of the FPC, the ACF bonder resin is on a surface of the alignment film 9 provided on the array substrate. Thus, it will not cover the side edge faces of the glass formed by the separation, and only the cut face can be exposed without covering.

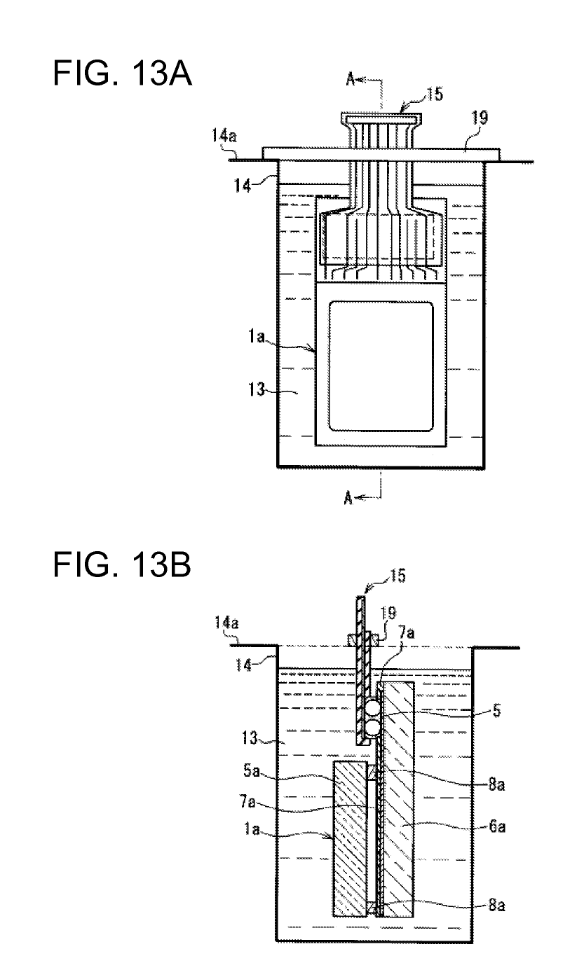

Next, the side edge faces of the glass are etched by submerging the liquid crystal display panel in a state in which it is clamped with the FPC 15 in a glass etching liquid (for example, 3 to 5% hydrofluoric acid liquid) to the part of the FPC 15 for 1 to 10 minutes (S7). This way, scars due to the separation can be removed by the glass etching. FIG. 13A is a view of the liquid crystal display panel being etched as viewed from the panel surface side. FIG. 13B is a cross sectional view along the line A-A in FIG. 13A. In the example shown in FIG. 13A and FIG. 13B, the liquid crystal display panel is fixed in an etching liquid 13 by hanging a clamp 19 holding the FPC 15 or a frame 14a of a container containing the etching liquid 13. By etching the liquid crystal panel in this state, all of the surfaces except for the film surfaces of the glass can be etched.

According to the present embodiment, similar to Embodiment 1, the protective film (alignment film 7) for etch protection is formed in the position crossing the separation line before the separation. Thus, such effects as forming the protective film up to the separation edges and no drooping of the protective film on the cut faces are achieved.

Further, since the protective film is formed by the patterning of the alignment film 7, the fabrication steps are further simplified. Also, by connecting the FPC, which is an example of wiring covered by the polyimide resin, to a wiring connection terminal beforehand, the liquid crystal display panel can be etched while fixing it by the FPC.

Embodiments of the present invention have been described. However, the present invention is not limited to the above described embodiments. For example, the present invention is applicable to a display panel used in a curved display. In the curved display using a glass substrate, glass thickness needs to be thin. As a technique to achieve this, there is a technique of thinning a liquid crystal panel after the attachment of the substrates by an etching process. By applying the present invention to this etching process, strength of the substrate can be increased.

Also, in the embodiments described above, the display panel using glass substrates was described. However, the present invention is applicable similarly to a display panel using resin substrates.

Also, in FIG. 1, the example of providing the protective film on one side of the periphery of the substrate was described. However, a display panel in the present invention is not limited to this. Specifically, the cases of having the protective films formed on two sides or on all of the four sides of a substrate are not to be excluded. Also, the number of FPCs connected to a substrate is not limited. Two or more FPCs may be connected to a substrate.

### DESCRIPTION OF REFERENCE CHARACTERS

1 . . . liquid crystal display panel
2 . . . display area
5 . . . opposite substrate
6 . . . array substrate
7 . . . alignment film
8 . . . seal
9 . . . protective film
11a . . . protective resin
16 . . . conductive wiring
17 . . . insulating body layer
18 . . . external connection wiring

1. A method for fabricating a display panel, comprising:
forming circuit wiring in each of a plurality of areas that are to become display panels on a substrate member;
forming a protective film for covering at least a part of the substrate member and the circuit wiring so as to cross a cutting line of the substrate member for separating each of the display panels;
separating each display panel by cutting the substrate member along the cutting line after the protective film is formed; and
etching a cut face of the separated display panel.

2. The method of fabricating a display panel according to claim 1, wherein the circuit wiring formed in each of the plurality of areas that are to become display panels includes external connection wiring that connects to a part external to the display panel,
wherein the protective film is formed so as to cover an area where the external connection wiring is formed and to expose a terminal portion of the external connection wiring that is to be connected to external wiring, and
wherein during the etching, the cut face of the display panel is etched in a state in which an additional film is further provided on the exposed terminal portion and the additional film is removed after the etching.

3. The method of fabricating a display panel according to claim 1,
wherein the circuit wiring formed in each of the plurality of areas that are to become display panels includes external connection wiring that connects to an external part of the display panel,
wherein the protective film is formed so as to cover an area where the external connection wiring is formed and to expose a terminal portion of the external connection wiring that is to be connected to external wiring, and
wherein during the etching, the cut face of the display panel is etched in a state in which wiring that is covered with resin is connected to the exposed terminal portion.

4. The method of fabricating a display panel according to claim 1, wherein the protective film is formed by forming an alignment film covering an display area of the display panel so as to cross at least one side of the periphery of a rectangular area that each display panel occupies on the substrate member.

5. A display panel comprising:
a substrate;
circuit wiring for displaying an image formed on a display area of the substrate; and
a protective film that covers at least a part of the substrate and the circuit wiring, wherein a side edge face of the protective film and a side edge face of the substrate are formed in a same plane.

6. The display panel according to claim 5,
wherein the circuit wiring includes external connection wiring that connects to a part external to the display panel,
wherein the protective film is formed so as to cover an area where the external connection wiring is formed and to expose a terminal portion of the external connection wiring that is to be connected to external wiring, and
wherein wiring covered with resin is connected to the exposed terminal portion.

7. The display panel according to claim 6, wherein the protective film covers an area where the external connection wiring is formed, and is an alignment film that has a side edge face in a same plane as one side edge face of the substrate.
